(19) United States
(12) Patent Application Publication
(10) Pub. No.: US 2023/0034713 A1
(43) Pub. Date: Feb. 2, 2023

(54) AUXILIARY CONTROL CIRCUIT FOR POWER AMPLIFICATION MODULE, POWER AMPLIFICATION MODULE, AND COMMUNICATION DEVICE

(71) Applicant: COMBA NETWORK SYSTEMS COMPANY LIMITED, Guangzhou (CN)

(72) Inventors: Jinxiong ZHU, Guangzhou (CN); Qiyan FAN, Guangzhou (CN); Luping XIE, Guangzhou (CN); Xiaosong ZENG, Guangzhou (CN); Jiangtao LIU, Guangzhou (CN)

(21) Appl. No.: 17/757,965

(22) PCT Filed: Dec. 25, 2020
(86) PCT No.: PCT/CN2020/139316

§ 371 Date: Jun. 24, 2022

(30) Foreign Application Priority Data
Dec. 27, 2019 (CN) 201911379604.0

(51) Int. Cl. H03F 3/24; H03F 3/72

(52) U.S. Cl. CPC H03F 3/245; H03F 3/72; H03F 2200/451; H03F 2200/462; H03F 2203/7236; H03F 2200/504

(57) ABSTRACT

An auxiliary control circuit (100) for a power amplification module, a power amplification module, and a communication device. The auxiliary control circuit (100) for the power amplification module comprises a main control chip (201), a current detection chip (12), and a precision adjustment unit (14). The precision adjustment unit (14) is connected in parallel to a precision control resistor of the current detection chip (12), and a switch control terminal of the precision adjustment unit (14) is electrically connected to the main control chip (201) and is used for adjusting an output voltage amplification factor of the current detection chip (12) when a switch signal outputted by the main control chip (201) is received. A detection input terminal of the current detection chip (12) is used for accessing a voltage to be measured of a power amplifier transistor power supply circuit (102) of the power amplification module. A detection output terminal of the current detection chip (12) is electrically connected to the main control chip (201). The main control chip (201) is used, upon receipt of a voltage signal outputted by the current detection chip (12), to measure and calculate so as to obtain a power amplification current corresponding to the voltage to be measured. By providing the precision adjustment unit (14) on the power amplification module for cooperation with the main control chip (201) and the current detection chip (12), the effect of greatly improving the detection precision of a power amplification current is achieved.

### TECHNICAL FIELD

The present disclosure relates to the field of current detection technologies, and specifically to an auxiliary control circuit for a power amplification module, a power amplification module, and a communication device.

### BACKGROUND

With the continuous development of power electronics technologies, current detection of a power amplification module is necessary in a variety of communication devices of a modern communication system. Through the current detection, an operating current of the power amplification module in the communication device can be determined, and the detected operating current can also be used as a warning or power amplification feedback control quantity of the communication system. As an important part of the communication system, the power amplification module has a main function of amplifying a communication signal so as to achieve a larger range of coverage and a greater transmission data amount.

For the current detection of the power amplification module, conventional current detection manners include sensing resistor and integrated operational amplifier detection, current transformer detection, Hall sensor detection, optical coupling isolation current detection, and capacitive isolation current detection. However, during the implementation of the present disclosure, the inventors find that the conventional power amplification current detection manners have a problem of low detection accuracy.

### SUMMARY

Based on the above, there is a need to provide an auxiliary control circuit for a power amplification module, a power amplification module, and a communication device with respect to the above problems existing in the conventional power amplification current detection manners.

In order to achieve the above objective, the following technical solutions are provided in embodiments of the present disclosure.

In one aspect, the present disclosure provides an auxiliary control circuit for a power amplification module, including a main control chip, a current detection chip, and a precision adjustment unit.

The precision adjustment unit is connected in parallel to a precision control resistor of the current detection chip, and the precision adjustment unit has a switch control terminal electrically connected to the main control chip and is configured to adjust an output voltage amplification factor of the current detection chip when receiving a switch signal output by the main control chip.

A detection input terminal of the current detection chip is configured to receive a voltage of a power amplifier transistor power supply circuit of the power amplification module to be measured, a detection output terminal of the current detection chip is electrically connected to the main control chip, and the main control chip is configured to estimate a power amplification current corresponding to the voltage to be measured after receiving a voltage signal output by the current detection chip.

In another aspect, a power amplification module is further provided, including a radio frequency link and the auxiliary control circuit described above.

In a further aspect, a communication device is further provided, including the power amplification module described above.

Each of the above technical solutions has the following advantages and beneficial effects.

According to the auxiliary control circuit, the power amplification module, and the communication device, by providing the precision adjustment unit on the power amplification module for cooperation with the main control chip and the current detection chip, the precision adjustment unit is turned on under the control of the switch signal of the main control chip and is connected to the current detection chip together with the precision control resistor to adjust a resistance value of a resistor connected to the current detection chip, so that an output voltage amplification factor of the current detection chip is variable. Since a static current is generally much lower than an operating current and requires higher measurement precision, through switch control over the precision adjustment unit, the current detection chip can achieve high voltage output precision when detecting a static current of the power amplifier transistor power supply circuit, and achieve lower voltage output precision than that in the static state when detecting an operating current of the power amplifier transistor power supply circuit, instead of completing the current detection in a whole process of the power amplifier transistor power supply circuit by a current detection chip, which effectively solves the problem of low detection precision in the conventional power amplification current detection manners and achieves an effect of greatly improving the detection precision of a power amplification current.

### BRIEF DESCRIPTION OF THE DRAWINGS

FIG. 1 is a block diagram illustrating a radio frequency link of a conventional power amplification module.

FIG. 2 is a schematic diagram illustrating a curve of voltage vs. current in conventional power amplification current detection.

FIG. 3 is a schematic structural diagram illustrating a first configuration of an auxiliary control circuit of a power amplification module according to an embodiment.

FIG. 4 is a schematic diagram illustrating a circuit configuration of a current detection chip according to an embodiment.

FIG. 5 is a schematic diagram illustrating a curve of voltage vs. current in power amplification current detection of the present disclosure according to an embodiment.

FIG. 6 is a schematic structural diagram illustrating a second configuration of the auxiliary control circuit of the power amplification module according to an embodiment.

FIG. 7 is a schematic structural diagram illustrating a third configuration of the auxiliary control circuit of the power amplification module according to an embodiment.

FIG. 8 is a schematic structural diagram illustrating a fourth configuration of the auxiliary control circuit of the power amplification module according to an embodiment.

FIG. 9 is a schematic structural diagram illustrating a fifth configuration of the auxiliary control circuit of the power amplification module according to an embodiment.

FIG. 10 is a schematic structural diagram illustrating a sixth configuration of the auxiliary control circuit of the power amplification module according to an embodiment.

FIG. 11 is a schematic structural diagram illustrating a power amplification current detection circuit of a communication device according to an embodiment.

### DETAILED DESCRIPTION OF THE EMBODIMENTS

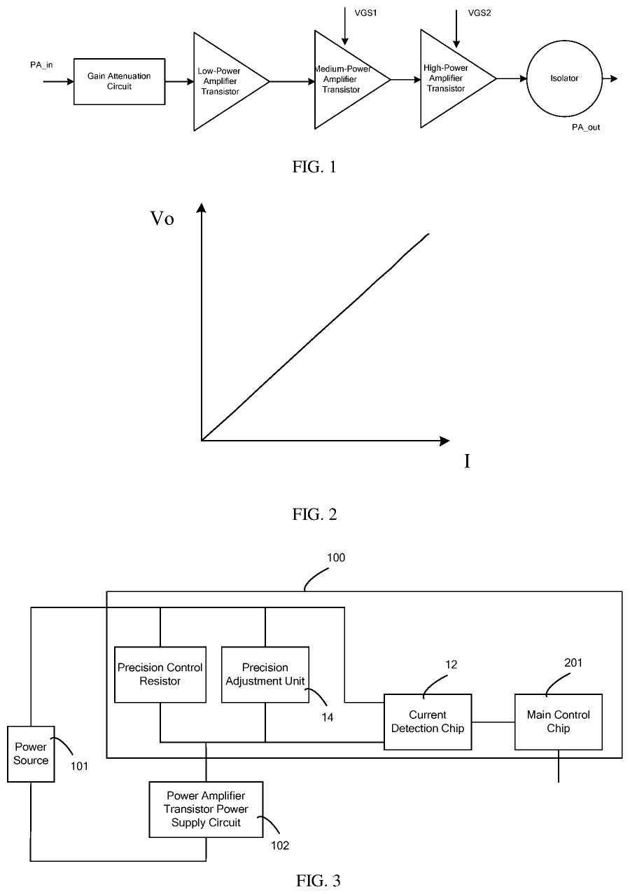

A power amplification module is mainly formed by a radio frequency link and an auxiliary control circuit. The radio frequency link is mainly formed by power amplifier devices, such as gain attenuation circuit, pre-drive-stage low-power amplifier transistor, drive-stage medium-power amplifier transistor, and final-stage high-power amplifier transistor, in cascade connection with an isolator or the like. According to requirements for gain magnitude of the power amplification module, two or more pre-drive stages may be used for cascade in the case of a higher gain requirement. According to different functions, the auxiliary control circuit roughly includes any one or more of a power conversion circuit, a detection circuit, an I0 external interface circuit, a warning circuit, a control circuit and a linearization circuit. A block diagram illustrating a radio frequency link of a common power amplification module is as shown in FIG. 1.

Generally, a main core component of the power amplification module is a power amplifier transistor. There are many types of power amplifier transistors, among which power amplifier transistors made of materials such as LDMOS or GaN are common. Gain G and saturation power Pₛₐₜ of the power amplifier transistors also have different grades. The gain ranging from 17 dB to 22 dB is common for the power amplifier transistors. The saturation power Pₛₐₜ of the power amplifier transistors is available in different grades such as 10 W, 20 W, 50 W, 100 W and 400 W. Engineers may choose different power amplifier transistors according to actual application requirements to achieve power amplification and realize corresponding link functions.

In order to amplify an input signal Pin to the gain and power value required by actual use of a whole communication system, power amplifier transistors of different power levels are generally cascaded to amplify the signal and achieve rational use of the gain and the saturation power Pₛₐₜ of the power amplifier transistors. For the power amplifier transistors, there are two important indicators to pay attention to in actual use, namely, a static current and an operating current. The static current is a current of the power amplifier transistor without an input power. The static current is controlled by magnitude of a gate voltage of the power amplifier transistor (i.e., gate voltages VGS1 and VGS2 as shown in FIG. 1). The static current reflects an initial operating state and a static operating point of the power amplifier transistor. Power amplifier transistors with different saturated powers Pₛₐₜ have different static currents. Generally, the lower the saturation power Pₛₐₜ, the lower the static current of the power amplifier transistor. For example, the static current ranges from about 100 mA to 200 mA for the saturation power Pₛₐₜ of 20 W, and the static current ranges from about 1000 mA to 2000 mA for the saturation power Pₛₐₜ of 400 W.

The operating current is a dynamic current during the operation compared with the static current. The magnitude of the operating current of the power amplifier transistor is related to the magnitude of signal power of the power amplifier transistor and reflects efficiency and an operating state of the power amplifier transistor. The operating current can be used to determine whether the power amplifier transistor is in a normal operating state and whether the efficiency is high or low. Power amplifier transistors with different efficiency and different output power have different operating currents. For example, if the power amplification module outputs radio frequency power of 80 W when powered by 28 V, a general operating current is in a range of 8 A to 10 A.

In conventional applications, the static current of the power amplifier transistor is generally required to be read by a current detection chip, so as to automatically adjust and set a gate voltage of the power amplifier transistor for the power amplification module. The operating current of the power amplifier transistor is read by the current detection chip to calculate the efficiency of the power amplification module and determine whether the power amplification module is abnormal. Common current detection chips include INA138 and INA168 series chips of Texas Instruments (TI), MAX4173 and MAX4375 chips of MAXIM, and ADM4073 chip of Analog Devices (ADI). An integrated and optimized current detection integrated circuit (IC) chip is featured with a small size, high precision, and good performance, and is widely used in printed circuit boards.

In the application of integrated current detection chips, any current detection chip is mainly formed by the following three parts: a sensing resistor, a detection chip body, and a detection voltage external amplifier circuit. An implementation principle is as follows. The sensing resistor on a detection input terminal of the chip may be connected to a current path under test, a current flowing therethrough may generate a voltage drop on the sensing resistor, the detection chip body may process the voltage drop through an internal precise differential amplifier circuit, and then the detection voltage external amplifier circuit may amplify a detection voltage value corresponding to the voltage drop to an appropriate value and output the voltage value.

In practical application, the inventors find that the static current and the operating current of the power amplifier transistor are quite different from each other when the conventional current detection chip is used in the power amplification module. For example, the static current ranges from 100 mA to 1200 mA, while the operating current ranges from 0 A to 10 A. For detection voltages finally output by the detection voltage external amplifier circuit, the detection voltages in the form of analog signals are all converted into corresponding digital signals by an AD (analog-to-digital conversion) chip and then enter MCUs or main control chips of other programmable logic circuits. The digital signals are processed by the main control chips or converted directly by using AD ports inside the main control chips. Generally, a maximum analog input detection voltage of an AD port cannot exceed 3.3 V or 5 V, so there may be a problem in practical use. It is assumed that a maximum analog voltage detected by the main control chip of the power amplification module is 5 V, a maximum operating current of the power amplification module is 10 A, the static current of a drive stage is 150 mA, and the static current of the final stage is 600 mA. When the common current detection chip is used in conjunction with the main control chip for current detection, a detection voltage Vo output by the current detection chip is linearly proportional to a detection current I measured by the main control chip based on the detection voltage Vo, as shown in FIG. 2.

Vo=K*I, where K denotes a slope, that is, current detection precision. The larger K is, the larger the detection voltage Vo is in the case of a same change in the detection current I, which is more easily detected by the MCU or AD. That is, the detection precision is higher. For example, when the detection current changes by 10 mA, if the detection voltage only changes by 0.5 mV, it is difficult to accurately detect the change of 0.5 mV in this case. If the detection current changes by 10 mA and the detection voltage changes by 10 mV, the detection voltage of 10 mV can be accurately detected.

For example, when a current I of a current path under test is 10 A, a detection voltage output by the current detection chip is 5.0 V. For example, when I=5 A, the detection voltage Vo is 2.5 V. That is, the current detection precision is that 1 A corresponds to 500 mV and 10 mA corresponds to 5 mV, and the current detection precision is constant. In practical use of the power amplification module, the current detection precision is required to be higher in the detection of the static current. For example, the precision that 10 mA corresponds to 10 mV can be achieved to accurately detect the static current, which is conducive to accurate static flow control over a gate voltage of the power amplifier transistor on the power amplification module. In the detection of the operating current, since the operating current is relatively large, the detection precision that 1 A corresponds to 50 mV (10 mA corresponds to 0.5 mV) can also meet actual use requirements, such as current warning. That is, on the power amplification module, the detection precision is required to be higher when the current detection chip detects the static current, but the detection precision is required to be lower when the current detection chip detects the operating current, which cannot be achieved in the conventional current detection manners.

Referring to FIG. 3, in order to solve the problem of low detection precision in the power amplification current detection manner, in one embodiment, an auxiliary control circuit 100 for a power amplification module is provided. The auxiliary control circuit 100 includes a main control chip 201, a current detection chip 12, and a precision adjustment unit 14. The precision adjustment unit 14 is connected in parallel to a precision control resistor of the current detection chip 12. The precision adjustment unit 14 has a switch control terminal electrically connected to the main control chip 201 and is configured to adjust an output voltage amplification factor of the current detection chip 12 when a switch signal output by the main control chip 201 is received. A detection input terminal of the current detection chip 12 is configured to receive a voltage of a power amplifier transistor power supply circuit 102 of the power amplification module to be measured. A detection output terminal of the current detection chip 12 is electrically connected to the main control chip 201. The main control chip 201 is configured to estimate a power amplification current corresponding to the voltage to be measured after receiving a voltage signal output by the current detection chip 12.

It may be understood that the current detection chip 12 may be an existing current detection chip 12 in the field, for example, the current detection chip 12 of any model illustrated in the above examples. The detection precision of the current detection chip 12 is associated with an output voltage amplification factor. That is, the higher the output voltage amplification factor, the higher the current detection precision. The output voltage amplification factor is determined by a resistance value of the precision control resistor of the current detection chip 12, that is, a current sensing resistor R14 and/or a resistor R31 in an external amplifier circuit. A specific resistance value may be selected according to detection precision required in practical application. Therefore, by using the precision adjustment unit 14 to adjust the resistance of the precision control resistor connected to the current detection chip 12, the detection precision when the current detection chip 12 detects the static current can be higher than that when the current detection chip 12 detects the operating current, so as to ensure the higher precision required by the detection of the static current and improve the accuracy of the control over the gate voltage of the power amplifier transistor of the power amplification module.

The power amplifier transistor power supply circuit 102 of the power amplification module refers to a circuit through which a power source 101 of the power amplification module supplies power to a drive-stage power amplifier transistor and a final-stage power amplifier transistor. The current sensing resistor in the detection input terminal of the current detection chip 12 is electrically connected to the power amplifier transistor power supply circuit 102 in a conventional connection manner in the field, so that a current in the power amplifier transistor power supply circuit 102 can flow through the current sensing resistor in the detection input terminal of the current detection chip 12, thereby enabling the current detection chip 12 to detect a voltage on its current sensing resistor corresponding to the current flowing therethrough, that is, a detection voltage. The precision adjustment unit 14 is a resistor element or combined circuit with a switch function, and configured to connect an internal resistor in parallel to the precision control resistor after an internal switch is turned on, so as to adjust a resistance value of the precision control resistor actually connected to the current detection chip 12, thereby achieving an effect of controlling the output voltage amplification factor of the current detection chip 12.

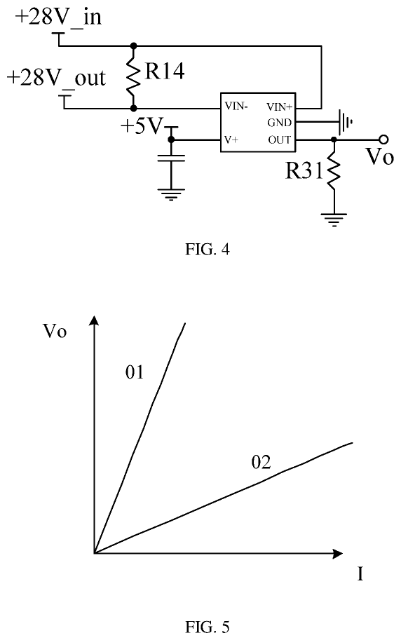

The main control chip 201 is an existing MCU or other types of control chips on the power amplification module in the field, which has a radio frequency link control function, a current estimation function, and other control functions required by the power amplification module. The main control chip 201 may be a control chip of the auxiliary control circuit, or a total control unit arranged on the power amplification module, or an auxiliary control chip arranged independently outside. The main control chip 201 is configured to estimate a corresponding static current after receiving a static voltage output by the current detection chip 12, to automatically control adjustment of a gate voltage of the power amplifier transistor, and configured to estimate a corresponding operating current after receiving an operating voltage output by the current detection chip 12, to implement monitoring and early warning of the operating current of the power amplification module. It is to be noted that, for ease of description, drawings taking an INA138 series current detection chip 12 as an example are given in the specification. FIG. 4 shows a circuit configuration of an INA138 chip, and other types of current detection chips 12 may be understood similarly. It is to be noted that FIG. 3 shows an example in which the precision control resistor is the current sensing resistor R14.

Specifically, when the power source 101 of the power amplification module starts to supply power for driving, the main control chip 201 outputs a switch signal to the precision adjustment unit 14 to control the precision adjustment unit 14 to be turned off, to enable the precision adjustment unit 14 to be disconnected from the circuit in this case. The current sensing resistor in the detection input terminal of the current detection chip 12 may generate a corresponding voltage drop, that is, the static voltage. The current detection chip 12 differentially amplifies, through its own internal precise differential amplifier circuit, the static voltage to a voltage that meets voltage input requirements of the main control chip 201, and then outputs the static voltage to the main control chip 201. The main control chip 201 automatically reads the static voltage output by the current detection chip 12 with higher detection precision, so as to estimate, according to the static voltage, a static current in an initial state when the power amplification module starts operating, to determine whether the static current is consistent with a set static current (or referred to as a standard static current). If the static current is not consistent with the set static current, the main control chip 201 may directly or indirectly control the magnitude of the gate voltage of the power amplifier transistor of the power amplification module to adjust the static current to the set magnitude.

When it is determined that the static current is consistent with the set static current, the main control chip 201 outputs another switch signal to the precision adjustment unit 14 to control the precision adjustment unit 14 to be turned on, to enable the precision adjustment unit 14 to be connected in parallel to the current detection chip 12 in this case. The output voltage amplification factor of the current detection chip 12 may be reduced due to the parallel connection of the precision adjustment unit 14. Therefore, in a case where the main control chip 201 automatically reads the operating voltage output by the current detection chip 12, the detection precision is lower than that of the static current. The main control chip 201 may estimate, in real time, the corresponding operating current based on the operating voltage output by the current detection chip 12 during the operation after the normal start of the power amplification module, so as to determine whether overcurrent occurs in the operating current, if yes, may automatically implement a power amplification current warming function, and if no, may continuously monitor the magnitude of the operating current of the power amplification module or display the operating current of the power amplification module in real time with an equipped display unit.

It is to be noted that the precision adjustment unit 14 may be connected to the current sensing resistor R14 side of the current detection chip 12 or connected to the resistor R31 side in the external amplifier circuit, or two or more precision adjustment units 14 may be provided so as to connect at least one precision adjustment unit 14 to the current sensing resistor R14 side and the resistor R31 side respectively, which may be specifically determined according to an adjustment requirement for the output voltage amplification factor of the current detection chip 12 in practical application, provided that the auxiliary control circuit 100 for the power amplification module can provide at least two kinds of different current detection precision.

With the above precision adjustment unit 14, the precision adjustment unit 14 is controlled to be turned off when low current flows through the power amplifier transistor power supply circuit 102 of the power amplification module, so that the output voltage amplification factor of the current detection chip 12 is relatively large, and the detection precision of the static current is higher when the static current is detected with the main control chip 201, which is more conducive to the static flow control over the gate voltage of the power amplifier transistor on the power amplification module. The precision adjustment unit 14 is controlled to be turned on when high current flows through the power amplifier transistor power supply circuit 102 of the power amplification module, so that the output voltage amplification factor of the current detection chip 12 is relatively low, which is more suitable for low detection precision of a relatively large operating current in the case of warning when the operating current is detected with the main control chip 201. In this way, the overall power amplification current detection has higher precision in the case of a low current (static current), and lower precision in the case of a high current (operating current), so as to meet actual application requirements of the low current and the high current. The precision adjustment unit 14 is configured to adjust the output voltage amplification factor of the current detection chip 12 to achieve variable current detection precision, which can be applied to different application scenarios. The detection precision of the auxiliary control circuit 100 for the power amplification module is as shown in FIG. 5. 01 represents a curve of detection precision of the current detection chip 12 when the static current is detected, and 02 presents a curve of detection precision of the current detection chip 12 when the operating current is detected.

According to the auxiliary control circuit 100 for the power amplification module, by providing the precision adjustment unit 14 on the power amplification module for cooperation with the main control chip 201 and the current detection chip 12, the precision adjustment unit 14 is turned on under the control of the switch signal of the main control chip 201 and is connected to the current detection chip 12 together with the precision control resistor to adjust a resistance value of a resistor connected to the current detection chip 12, so that the output voltage amplification factor of the current detection chip 12 is variable. Since a static current is generally much lower than an operating current and requires higher measurement precision, through switch control over the precision adjustment unit 14, the current detection chip 12 can achieve high voltage output precision when detecting a static current of the power amplifier transistor power supply circuit 102, and achieve lower voltage output precision than that in the static state when detecting an operating current of the power amplifier transistor power supply circuit 102, instead of completing the current detection in a whole process of the power amplifier transistor power supply circuit by a current detection chip 12, which effectively solves the problem of low detection precision in the conventional power amplification current detection manners and achieves an effect of greatly improving the detection precision of a power amplification current.

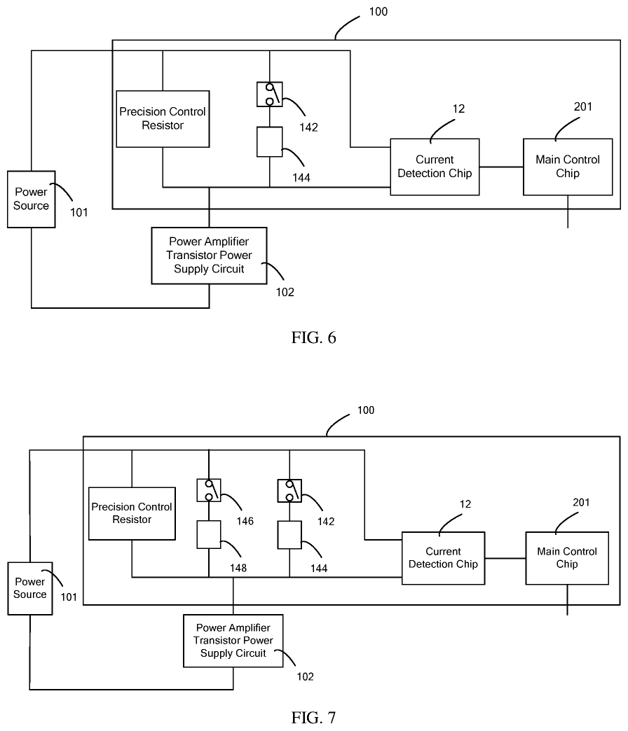

Referring to FIG. 6, in one embodiment, the precision adjustment unit 14 includes a first programmed switch 142 and a first auxiliary resistor 144. A switch control terminal of the first programmed switch 142 is electrically connected to the main control chip 201. An input terminal of the first programmed switch 142 is electrically connected to a first terminal of the precision control resistor, and an output terminal of the first programmed switch 142 is electrically connected to a first terminal of the first auxiliary resistor 144. A second terminal of the first auxiliary resistor 144 is electrically connected to a second terminal of the precision control resistor. The precision control resistor is a current sensing resistor or an external amplification resistor of the current detection chip 12.

It may be understood that the first programmed switch 142 may be any existing programmed switch, which may be specifically selected according to the number of switching paths required by the application. A resistance value of the first auxiliary resistor 144 may be determined according to an adjustment requirement for the output voltage amplification factor of the current detection chip 12, which may be determined according to, for example, an output voltage amplification factor and a resistance value of the current sensing resistor (or the external amplification resistor) required by the detection of the operating current in actual application scenarios and based on the principle of parallel connection of resistors. The external amplification resistor is the resistor R31 described above. In this embodiment, the first programmed switch 142 and the first auxiliary resistor 144 connected in series may be connected to the current sensing resistor side of the current detection chip 12, or connected to the resistor R31 side of the current detection chip 12, both of which enable the first auxiliary resistor 144 to be disconnected or connected in parallel by controlling the first programmed switch 142 to be turned on or turned off, so as to achieve an effect of adjusting the output voltage amplification factor of the current detection chip 12.

The combined application of the first programmed switch 142 and the first auxiliary resistor 144 can effectively achieve an effect that the current detection chip 12 has high voltage output precision when detecting the static current of the power amplifier transistor power supply circuit 102 and lower voltage output precision than that in the static state when detecting the operating current of the power amplifier transistor power supply circuit 102, and can lead to lower application costs.

Referring to FIG. 7, in one embodiment, the precision adjustment unit 14 further includes a second programmed switch 146 and a second auxiliary resistor 148. A switch control terminal of the second programmed switch 146 is electrically connected to the main control chip 201. An input terminal of the second programmed switch 146 is electrically connected to the first terminal of the precision control resistor. An output terminal of the second programmed switch 146 is electrically connected to a first terminal of the second auxiliary resistor 148. A second terminal of the second auxiliary resistor 148 is electrically connected to the second terminal of the precision control resistor.

It may be understood that the second programmed switch 146 may be a programmed switch with a same model as the first programmed switch 142, or a programmed switch with a different model from the first programmed switch 142, provided that the second auxiliary resistor 148 can be controlled to be connected and disconnected under the control of the main control chip 201. The second auxiliary resistor 148 may be the same as or different from the first auxiliary resistor 144. A resistance value of the second auxiliary resistor 148 may be determined according to an adjustment requirement for the output voltage amplification factor of the current detection chip 12.

Specifically, in this embodiment, two precision adjustment units 14 are designed on the current sensing resistor side or the resistor R31 side of the current detection chip 12, and the main control chip 201 may control turn-on and turn-off of the two programmed switches respectively to respectively achieve adjustment of highest detection precision when no auxiliary resistor is connected, adjustment of second highest detection precision when one auxiliary resistor is connected, and adjustment of lowest detection precision when the two auxiliary resistors are connected, so that the auxiliary control circuit 100 for the power amplification module can support three kinds of different detection precision of the power amplification current, thereby achieving more refined current detection for the power amplification module.

The use of two precision adjustment units 14 can support three kinds of different current detection precision during the detection of the power amplification current, which further improves the detection precision of the power amplification current.

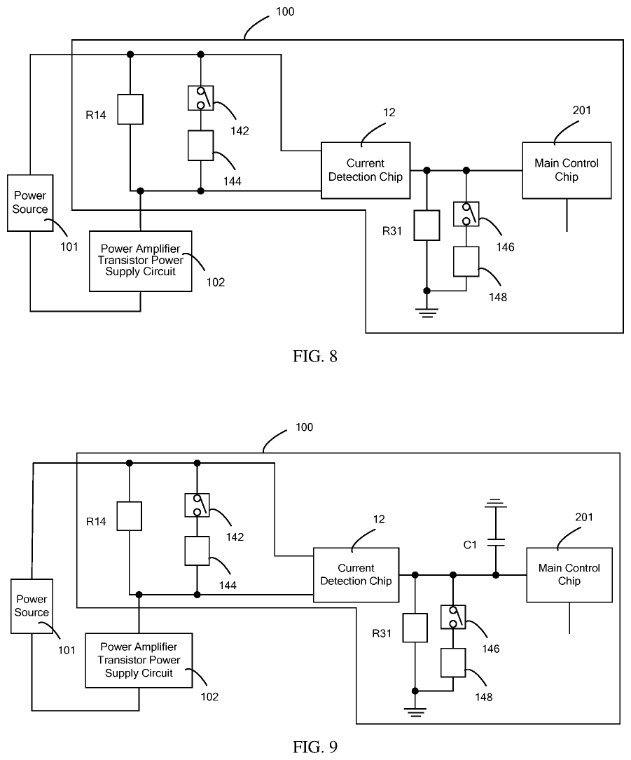

Referring to FIG. 8, in one embodiment, the precision adjustment unit 14 includes a first programmed switch 142 and a first auxiliary resistor 144 connected in series, and a second programmed switch 146 and a second auxiliary resistor 148 connected in series, and the precision control resistor is a current sensing resistor R14 and an external amplification resistor R31 of the current detection chip 12. A switch control terminal of the first programmed switch 142 is electrically connected to the main control chip 201. An input terminal of the first programmed switch 142 is electrically connected to a first terminal of the current sensing resistor. A second terminal of the first auxiliary resistor 144 is electrically connected to a second terminal of the current sensing resistor. A switch control terminal of the second programmed switch 146 is electrically connected to the main control chip 201. An input terminal of the second programmed switch 146 is electrically connected to a first terminal of the external amplification resistor. A second terminal of the second auxiliary resistor 148 is electrically connected to a second terminal of the external amplification resistor.

It may be understood that, in this embodiment, a precision adjustment unit 14 may be arranged on the current sensing resistor R14 side and the resistor R31 side of the current detection chip 12 respectively. The main control chip 201 may control turn-on and turn-off of the two programmed switches respectively to achieve three kinds of different detection precision.

Specifically, at a detection stage of the static current of the power amplification module, the main control chip 201 may output switch signals to the two programmed switches respectively to control the two programmed switches to be turned off to disconnect the two auxiliary resistors. In this case, the output voltage amplification factor of the current detection chip 12 is maintained to the maximum, so as to meet the requirement of high-precision detection at a low current. At a detection stage of the operating current of the power amplification module, the main control chip 201 may output switch signals to the two programmed switches respectively to control either or both of the two programmed switches to be turned on to enable either or both of the two auxiliary resistors to be connected to a detection loop. In this case, the output voltage amplification factor of the current detection chip 12 is switched to a medium level or minimum level, so as to meet the requirement of relatively-low-precision detection at a high current.

The arrangement of a precision adjustment unit 14 on the current sensing resistor side and the resistor R31 side of the current detection chip 12 can also support three kinds of different current detection precision during the detection of the power amplification current, which further improves the detection precision of the power amplification current.

In one embodiment, with reference to the above design idea, persons skilled in the art can also arrange more precision adjustment units 14 on the current sensing resistor side and/or the resistor R31 side of the current detection chip 12 according to refined detection and control requirements of current detection in practical applications, so as to meet adjustment requirements of more current detection precision and further improve the current detection precision.

Referring to FIG. 9, in one embodiment, the auxiliary control circuit for the power amplification module further includes a filter capacitor C1. One terminal of the filter capacitor C1 is electrically connected between the detection output terminal of the current detection chip 12 and the main control chip 201. The other terminal of the filter capacitor C1 is grounded.

It may be understood that, in this embodiment, the filter capacitor C1 may also be connected between the detection output terminal of the current detection chip 12 and the main control chip 201 to filter out clutter on the detection output terminal of the current detection chip 12, enabling an output DC voltage to be more stable. Parameter specifications of the filter capacitor C1 may be selected according to a power supply mode of the power amplification module and output characteristics of the current detection chip 12 in practical application, provided that a required clutter filtering function can be effectively provided. With the application of the filter capacitor C1, a filtering function is provided between the current detection chip 12 and the main control chip 201, so that the output voltage of the current detection chip 12 is more stable, which eliminates the interference of the clutter with the power amplification current detection, thereby further improving the detection precision of the power amplification current.

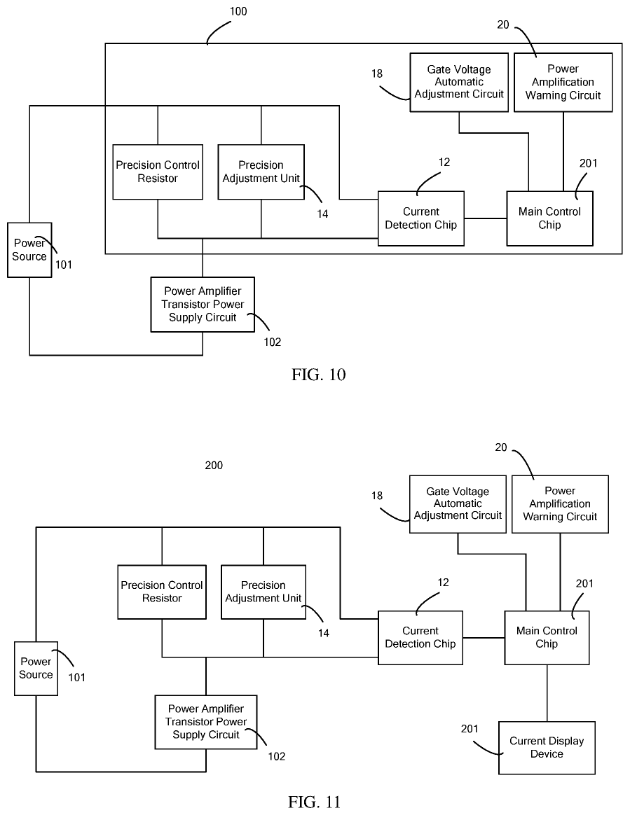

Referring to FIG. 10, in one embodiment, the auxiliary control circuit 100 for the power amplification module further includes a gate voltage automatic adjustment circuit 18. An input terminal of the gate voltage automatic adjustment circuit 18 is used for electrically connecting the main control chip 201. The gate voltage automatic adjustment circuit 18 is configured to adjust the magnitude of a gate voltage of a power amplifier transistor of the power amplification module after receiving a static current adjustment signal output by the main control chip 201.

It may be understood that the gate voltage automatic adjustment circuit 18 is an existing power amplifier transistor gate voltage automatic adjustment circuit in the field. Specifically, during the operation of the power amplification module, a static voltage detected and output by the current detection chip 12 is differentially amplified to an appropriate voltage, passes through the filter capacitor C1 to filter out clutter, and then enters the main control chip 201, for example, an MCU processing unit of the power amplification module. The MCU processing unit detects and obtains a corresponding static current based on the input static voltage, and compares the static current with a set static current to determine whether the current static current is correct. If the current static current is not correct, the MCU processing unit may automatically generate a corresponding static current adjustment signal and output the static current adjustment signal to the gate voltage automatic adjustment circuit 18. The gate voltage automatic adjustment circuit 18 may adjust the gate voltage of the corresponding power amplifier transistor based on the static current adjustment signal after receiving the static current adjustment signal. In this way, after adjusting the gate voltage, the MCU processing unit performs state current detection again based on the static voltage detected and output by the current detection chip 12, until the static current corresponding to the static voltage detected and output by the current detection chip 12 is consistent with the set static current or is within a floating range allowed by the set static current. If the current static current is correct, the MCU processing unit may receive and detect an operating current based on an operating voltage output by the current detection chip 12.

Through the cooperative application of the current detection chip 12, the main control chip 201, and the gate voltage automatic adjustment circuit 18, high-precision static current detection can be effectively realized, and high-precision gate voltage automatic adjustment of the power amplifier transistor can also be realized.

In one embodiment, as shown in FIG. 10, the auxiliary control circuit 100 for the power amplification module further includes a power amplification warning circuit 20. An input terminal of the power amplification warning circuit 20 is electrically connected to the main control chip 201. The power amplification warning circuit 20 is configured to provide warning about overcurrent of an operating current of the power amplification module after receiving a warning signal output by the main control chip 201.

It may be understood that the power amplification warning circuit 20 is a power amplification warning circuit 20 arranged in a conventional auxiliary control circuit in the field. Specifically, during the operation of the power amplification module, an operating voltage detected and output by the current detection chip 12 is differentially amplified to an appropriate voltage, passes through a filter capacitor C2 to filter out clutter, and then enters the main control chip 201. The main control chip 201 detects and obtains a corresponding operating current based on the input operating voltage, and compares the operating current with a set operating current (or referred to as a standard dynamic current) to determine whether the current operating current is excessively large. If the current operating current is excessively large, the main control chip 201 may automatically generate a corresponding warning signal and output the warning signal to the power amplification warning circuit 20. After receiving the warning signal, the power amplification warning circuit 20 may provide warning about overcurrent of an operating current of the power amplification module based on the warning signal. For example, current warning related information is uploaded to a main control unit of a device where the power amplification module is located or an external total control system. If the current operating current is not excessively large, the main control chip 201 may continuously receive and detect the operating current based on the operating voltage output by the current detection chip 12, or may output data of the operating current externally for linkage of external devices.

For easier understanding, on the power amplification module, the static current and the operating current are both currents on a power supply path of the same power source 101, which are illustrated with the design scheme shown in FIG. 6.

When there is a need to switch to a high-precision current detection mode, a switch signal output by the MCU processing unit controls the first programmed switch 142 to be turned off, and on-resistance in this case is resistance R₁ of the current sensing resistor R14. In this case, the voltage output by the current detection chip 12 is Vo=K*R₁*I, where K denotes current detection precision (which is a constant).

When there is a need to switch to a low-precision current detection mode, the switch signal output by the MCU processing unit controls the first programmed switch 142 to be turned on, and parallel resistance of the current sensing resistor R14 and the first auxiliary resistor 144 in this case is R_{1b}. R_{1b}<R₁ and R_{1b}<R_{b}, where R_{b} denotes resistance of the first auxiliary resistor 144. In this case, the voltage output by the current detection chip 12 is Vo=K*R_{1b}*I. Appropriate R₁ and R_{b} are selected according to actual use requirements, so that the current detection precision can be controlled by controlling turn-on of the first programmed switch 142. For example, when the gate voltage of the power amplification module is set, the gate voltage is required to be adjusted to the magnitude corresponding to the required static current. The static current is generally low (e.g., in a range of 100 mA to 900 mA), so relatively high detection precision is required. Then, the MCU processing unit may control the first programmed switch 142 to switch to a high-precision detection application mode. Upon completion of the setting of the required static current, the operating current will be detected. A current value of the operating current is much larger than that of the static current (the operating current ranges from 0 mA to 10 A), so, in order to ensure the current detection range of the auxiliary control circuit 100 for the power amplification module, detection precision can be sacrificed in exchange for a larger current detection range required. In this case, the MCU processing unit may control the first programmed switch 142 to switch to a low-precision detection application mode.

Taking an INA138 series current detection chip 12 as an example, it is assumed that the resistance R₁ of the current sensing resistor R14 is 0.5Ω, the current detection precision is K=8, the resistance R_{b} of the first auxiliary resistor 144 is 0.05Ω, the static current is 800 mA, and the operating current is 8 A. High detection precision is required when the static current is detected, and then the first programmed switch 142 is controlled to be turned off. In this case, according to the characteristic of the current detection chip INA138, Vo=0.5*K*I=4I. A large dynamic detection range is required when the operating current is detected. In this case, the first programmed switch 142 is controlled to be turned on, and according to the characteristic of the current detection chip INA138, Vo=0.04545*K*I=0.3636*I. If the static current is 800 mA, the output voltage in this case is Vo=4*0.8=3.6V. If the operating current is 8 A, the output voltage in this case is Vo=0.3636*8=2.9088V. As can be seen, through the above design, the current detection precision may be 10 times different, which meets the use requirements for different current detection precision in different power amplification current detection applications.

In one embodiment, a power amplification module is further provided, including a radio frequency link and the auxiliary control circuit 100 for the power amplification module described above.

It may be understood that the explanation of the auxiliary control circuit 100 for the power amplification module in this embodiment can be obtained with reference to the relevant explanation in each embodiment of the auxiliary control circuit 100 for the power amplification module, which is not expanded and repeated herein.

In the above power amplification module, through the combined application of the main control chip 201 and the auxiliary control circuit 100 for the power amplification module, the current detection precision is variable during the power amplification current detection, which can realize high-precision measurement of the static current. At the same time, the measurement precision of the operating current of the power amplifier transistor power supply circuit 102 can also be well met, instead of completing the current detection in a whole process of the power amplifier transistor power supply circuit by a current detection chip 12, which effectively solves the problem of low detection precision in the conventional power amplification current detection manners and achieves an effect of greatly improving the detection precision of a power amplification current.

In one embodiment, a communication device 200 is further provided, including the power amplification module described above.

It may be understood by persons skilled in the art that the communication device 200 may be a variety of devices in a communication system, which apply the power amplification module to detect and warn a power amplification current. The communication device may further include components other than the power amplification module, for example, but not limited to, a storage device, a transceiver antenna, a data conversion circuit, and so on.

In the communication device 200, through the application of the power amplification module, the current detection precision is variable during the power amplification current detection, which can realize high-precision measurement of the static current. At the same time, the measurement precision of the operating current of the power amplifier transistor power supply circuit 102 can also be well met, which effectively solves the problem of low detection precision in the conventional power amplification current detection manners and achieves an effect of greatly improving the detection precision of a power amplification current.

Referring to FIG. 11, in one embodiment, the communication device 200 further includes a current display device 201. The current display device 201 is electrically connected to the main control chip 201 of the power amplification module. The current display device 201 is configured to display an operating current of the power amplification module after receiving an operating current signal output by the main control chip 201. The operating current is a current corresponding to an operating voltage of the power amplifier transistor power supply circuit 102 of the power amplification module.

It may be understood that the current display device 201 is a display device with a data display or data display and broadcast function, such as a touch display, a non-touch display or an ordinary display without a control input function. The current display device 201 may be arranged independently of the power amplification module on the communication device 200 in the form of discrete elements, or may be integrally arranged in an integrated package. A specific arrangement manner may be determined according to a size and a shape of the current display device 201, auxiliary functions (such as touch input, key input or floating operation input).

Specifically, during the operation of the power amplification module, an operating voltage detected and output by the current detection chip 12 is differentially amplified to an appropriate voltage, passes through the filter capacitor C1 to filter out clutter, and then enters the MCU processing unit. The MCU processing unit detects and obtains a corresponding operating current based on the input operating voltage, and compares the operating current with a set operating current (or referred to as a standard dynamic current) to determine whether the current operating current is excessively large. If the current operating current is excessively large, the MCU processing unit may link the power amplification warning circuit 20 to provide warning about overcurrent of an operating current of the power amplification module. If the current operating current is not excessively large, the MCU processing unit may continuously receive and detect an operating current based on an operating voltage output by the current detection chip 12, and output a real-time operating current to the current display device 201. The current display device 201 may display data of the real-time operating current by means of numerical values or a curve, or numerical values and a curve, so that operation and maintenance staff can know the magnitude of the operating current of the power amplification module in the communication device 200 at any time, so as to determine an operating state of the power amplification module.

Through the combined application of the power amplification module and the current display device 201, a function of displaying an operating current in real time can be realized during the detection of the operating current of the power amplification module.

In one embodiment, the communication device 200 is any one of a repeater device, a remote radio device, a rail power amplifier device, and an integrated power amplifier and receiver.

It may be understood that the communication device 200 using the power amplification module described above may be any one of a repeater device, a remote radio device, a rail power amplifier device, and an integrated power amplifier and receiver in the field, so as to improve the detection precision of a power amplification current in a device, thereby controlling the gate voltage of the power amplifier transistor more accurately and completing the functions of power amplification warning or current display. It may be understood by persons skilled in the art that the above listed are only several common communication devices 200, and the power amplification module may also be applied to other devices required to have a power amplification current detection function.

1. An auxiliary control circuit for a power amplification module, the auxiliary control circuit comprising:
a main control chip, a current detection chip, and a precision adjustment unit, wherein:
the precision adjustment unit is connected in parallel to a precision control resistor of the current detection chip, and the precision adjustment unit has a switch control terminal electrically connected to the main control chip and is configured to adjust an output voltage amplification factor of the current detection chip when receiving a switch signal output by the main control chip; and
a detection input terminal of the current detection chip is configured to receive a voltage of a power amplifier transistor power supply circuit of the power amplification module to be measured, a detection output terminal of the current detection chip is electrically connected to the main control chip, and the main control chip is configured to estimate a power amplification current corresponding to the voltage to be measured after receiving a voltage signal output by the current detection chip.

2. The auxiliary control circuit of claim 1, wherein:
the precision adjustment unit includes a first programmed switch and a first auxiliary resistor, and a switch control terminal of the first programmed switch is electrically connected to the main control chip;
an input terminal of the first programmed switch is electrically connected to a first terminal of the precision control resistor, an output terminal of the first programmed switch is electrically connected to a first terminal of the first auxiliary resistor, and a second terminal of the first auxiliary resistor is electrically connected to a second terminal of the precision control resistor; and
the precision control resistor is a current sensing resistor or an external amplification resistor of the current detection chip.

3. The auxiliary control circuit of claim 2, wherein:
the precision adjustment unit further includes a second programmed switch and a second auxiliary resistor, a switch control terminal of the second programmed switch being electrically connected to the main control chip; and
an input terminal of the second programmed switch is electrically connected to the first terminal of the precision control resistor, an output terminal of the second programmed switch is electrically connected to a first terminal of the second auxiliary resistor, and a second terminal of the second auxiliary resistor is electrically connected to the second terminal of the precision control resistor.

4. The auxiliary control circuit of claim 1, wherein:
the precision adjustment unit includes a first programmed switch and a first auxiliary resistor connected in series, and a second programmed switch and a second auxiliary resistor connected in series, and the precision control resistor is a current sensing resistor or an external amplification resistor of the current detection chip;
a switch control terminal of the first programmed switch is electrically connected to the main control chip, an input terminal of the first programmed switch is electrically connected to a first terminal of the current sensing resistor, and a second terminal of the first auxiliary resistor is electrically connected to a second terminal of the current sensing resistor; and
a switch control terminal of the second programmed switch is electrically connected to the main control chip, an input terminal of the second programmed switch is electrically connected to a first terminal of the external amplification resistor, and a second terminal of the second auxiliary resistor is electrically connected to a second terminal of the external amplification resistor.

5. The auxiliary control circuit of claim 1, further comprising a gate voltage automatic adjustment circuit, wherein:
an input terminal of the gate voltage automatic adjustment circuit is electrically connected to the main control chip;
the gate voltage automatic adjustment circuit is configured to adjust the magnitude of a gate voltage of a power amplifier transistor of the power amplification module after receiving a static current adjustment signal output by the main control chip.

6. The auxiliary control circuit of claim 5, further comprising a power amplification warning circuit, an input terminal of the power amplification warning circuit being electrically connected to the main control chip, the power amplification warning circuit being configured to provide warning about overcurrent of an operating current of the power amplification module after receiving a warning signal output by the main control chip.

7. A power amplification module, comprising a radio frequency link and the auxiliary control circuit of claim 1.

8. A communication device, comprising the power amplification module of claim 7.

9. The communication device of claim 8, further comprising a current display device, wherein:
the current display device is electrically connected to the main control chip of the power amplification module;
the current display device is configured to display an operating current of the power amplification module after receiving an operating current signal output by the main control chip; and
the operating current is a current corresponding to an operating voltage of the power amplifier transistor power supply circuit of the power amplification module.

10. The communication device of claim 8, wherein the communication device is any one of a repeater device, a remote radio device, a rail power amplifier device, and an integrated power amplifier and receiver.
